(19) United States
(12) Patent Application Publication
(10) Pub. No.: US 2013/0127004 A1
(43) Pub. Date: May 23, 2013

(54) Image Sensor Module Package and Manufacturing Method Thereof

(71) Applicant: Shao-Pin Ru, New Taipei City (TW)

(72) Inventor: Shao-Pin Ru, New Taipei City (TW)

(73) Assignee: TONG HSING ELECTRONIC INDUSTRIES, LTD., Taipei City (TW)

(21) Appl. No.: 13/485,939

(22) Filed: Jun. 1, 2012

(30) Foreign Application Priority Data
Nov. 23, 2011 (TW) 100142810

(51) Int. Cl. H01L 31/02

(52) U.S. Cl. 257/443; 438/66; 257/E31.113

(57) ABSTRACT

An image sensor module includes a substrate, a circuit layer, a flip chip, an insulating layer, and a conducting layer. The substrate has at least one transparent area and defines a first surface and a second surface. The circuit layer is provided on the first surface of the substrate. The flip chip is connected to the circuit layer. The insulating layer substantially encases the flip chip and a part of the circuit layer, wherein the insulating layer has at least one groove at a lateral side of said insulating layer thereof each provided with a metal layer. The conducting layer is provided on a top surface of the insulating layer, wherein the conducting layer is electrically connected to the circuit layer via the metal layer.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

The present invention relates to sensor module package and a manufacturing method thereof, and more particularly to an image senor module package and a manufacturing method thereof.

2. Description of Related Arts

A conventional image sensor module package employs a wire bonding technology to electrically connect a chip with a printed circuit board. Accordingly, an image sensor chip is provided on a ceramic substrate, wherein the image sensor chip is electrically connected to the ceramic substrate in a wire bonding manner, and then a glass layer is attached on the top of the ceramic substrate and the chip. However, the chip only allows wire bonding around an outer contour edge thereof during a wire bonding packaging step, so that the number of pins received therein is thus limited. Accordingly, if an increase of the number of pins is desired, it is unavoidable to enlarge a packaging volume of the chip. Therefore, an overall size of the image sensor module package using wire bonding technology is relatively large that the image sensor module package couldn't be minimized to fulfill a product objective of being light and compact.

Another conventional image sensor module package utilizes a flip-chip packaging method which comprises the following steps: forming a circuit layer which is provided with metal bumps on a glass substrate, coating bonding glue on the metal bumps, fittingly coupling an image sensor chip with the circuit layer on the glass substrate via the metal bumps and the bonding glue, and finally filling with insulating epoxy material to coat the image sensor chip. The output/input contacts provided by the above flip-chip method are arranged in an array, and that in comparison with the wire bonding method, the number of output/input contacts of the chip is greatly increased assuming that the sizes of the chips are the same.

Recently, a new flip-chip packaging method has been developed. For example, in U.S. patent application, publication number US20060171698, an insulating compound is provided with a plurality of through holes penetrated therethrough, wherein each hole is plated with metal in such a manner that a first end of the metal is longitudinally aligned for electrically connecting to a conducting layer while a second end of the metal is exposed from a surface of the insulating compound to form as an interconnection trace between output and input contacts, so that this module can be easy to be mounted onto the system-level printed circuit board. However, because the through holes are formed in the insulating compound in such a manner that the periphery of each hole is closed to form a blind via, theses vias should be completely filled with metal when using a conventional method. During the plating procedure, voids and plating solution is easy to get trapped inside the vias, and may cause the reliability concerns when the packages operate at high temperature. Besides, the plated metal needs to be thick enough in order to fill up the blind via completely, however, due to the serious CTE-mismatch between metal and compound, the strong stress may happen to peel off the plated pads and lower the adhesion between plated metal and compound. Thus the credibility of the image sensor module package is decreased, as well as the reliability.

In order to solve the drawbacks in the aforesaid conventional arts and prior patent application, the present invention provides an image sensor module package having at least one groove provided at a lateral side of an insulating layer to enhance the reliability of the package and increase the input/output pin account of the image sensor module package.

### SUMMARY OF THE PRESENT INVENTION

A main object of the present invention is to provide an image sensor module package, wherein a relatively large soldering area is provided through at least one groove at a lateral side of an insulating layer, so that an desired effect, that the image sensor module package being firmly bonded to a system-level printed circuit board by a soldering and not being easy to peel off, is achieved.

Another object of the present invention is to provide an image sensor module package, wherein the groove at the lateral side of the insulating layer is plated with a thin metal conductor, wherein the thin metal conductor is electrically connected to a conducting layer and a circuit layer. Unlike the conventional art, the holes are completely filled with metal to form a metal column having electrically conducting ability, wherein during the plating procedure, trapped voids and solutions are easily produced, thereby they are not only difficult to be release out and may bring down the electrically and thermally performances, but also result in a bad reliability. However, according to the present invention, the groove provided in the insulating compound has an open side, so that it only needs to plate a thin metal layer in the groove to form an interconnection, thereby drawbacks of trapping voids and plating solutions are avoided.

Another object of the present invention is to provide an image sensor module package, wherein the groove with an open side, which is provided at the lateral side of the insulating layer, is plated with a thin metal layer to form an interconnection. Unlike the conventional art that needs metal filled vias and thick metal pads on the surface of insulating layer, the metal layer of the present invention only has a thickness less than 10 μm, so that unwanted drawbacks produced by thermal stress are prevented.

Another object of the present invention is to provide an image sensor module package, wherein a redistribution layer (RDL) is provided on a top surface of the insulating layer, so that the positions of output/input contacts can be changed by metal wiring so that the image sensor module package of the present invention can be incorporated with various component modules.

Additional advantages and features of the invention will become apparent from the description which follows, and may be realized by means of the instrumentalities and combinations particular point out in the appended claims.

According to the present invention, the foregoing and other objects and advantages are attained by an image sensor module comprising:

at least one substrate having at least one transparent area and defining a first surface and a second surface;

a patterned circuit layer on the first surface of the substrate;

a flip chip connected to the circuit layer;

an insulating layer substantially encasing the flip chip and a part of the circuit layer, wherein the insulating layer has at least one groove at a lateral side of the insulating layer thereof, wherein a metal layer is provided in each of the grooves; and

a conducting layer provided on a top surface of the insulating layer, wherein the conducting layer is electrically connected to the circuit layer via the metal layer.

In the aforesaid image sensor module package, the substrate, which is made of glass, is coated with opaque mask on the second surface to define a position and a shape of the transparent area.

In the aforesaid image sensor module package, the substrate, which is made of ceramic or organic material, has an opening penetrating the first surface and the second surface, wherein a glass layer is provided with respect to a position of the opening at the second surface to form the transparent area of the substrate.

In the aforesaid image sensor module package, the insulating layer completely encases the flip chip and substantially partly encases the circuit layer to expose a contacting surface of the circuit layer so as to be electrically connected to the metal layer in the groove.

In the aforesaid image sensor module package, the conducting layer is an output/input contact or a redistribution layer arranging output/input contacts around a top surface of the insulating layer in an array so as to rearrange positions of the output/input contacts.

In the aforesaid image sensor module package, the image sensor module package is bonded with a carrier board through a soldering paste, wherein the groove at the lateral side of the insulating layer has an open side proving an extra soldering area, so that the image sensor module package is firmly connected to the carrier board and is not easy to peel off, wherein the soldering paste is Sn paste or Pb-free soldering paste.

In the aforesaid image sensor module package, the flip chip comprises at least one contacting point electrically connected to the circuit layer, wherein the contacting point is a metal bump selected from a group consisting of Au bump, Sn bump, Cu bump, Ag bump, Ni bump, and Pb-free bump.

In the aforesaid image sensor module package, the insulating layer made of material selected from a group consisting of plastic molding compound, black epoxy-based, silicon-based, and other organic-based materials.

In the aforesaid image sensor module package, the metal layer is made of material selected from a group consisting of Cu, Ag, Au, or any other metal alloy.

In order to achieve the above objects, the present invention also provides a method for packaging an image sensor module, wherein the method comprises the following steps:

(a) Provide a substrate having at least one transparent area.

(b) Pattern a circuit layer on the substrate.

(c) Bond a flip chip to the circuit layer.

(d) Form an insulating layer with at least one groove at a lateral side of the insulating layer thereof, wherein the insulating layer substantially encases the flip chip and a part of the circuit layer.

(e) Provide a metal layer in the groove, and electrically connect the metal layer to the circuit layer.

(f) Provide a conducting layer on a top surface of the insulating layer, and electrically connect the conducting layer to the metal layer in the groove.

In the aforesaid method of packaging an image sensor module, the insulating layer having at least one groove is produced by a process selected from the group consisting of molding, etching, mechanical grinding and brushing, and laser machining.

In the aforesaid method of packaging an image sensor module, the groove is integrally formed with the insulating layer at the same time.

In the aforesaid method of packaging an image sensor module, the groove is provided after the insulating layer is formed.

Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a top view of an image sensor module package according to a first preferred embodiment of the present invention.

FIG. 2 is a sectional view of the image sensor module package according to the above first preferred embodiment of the present invention.

FIG. 3 is a top view of an image sensor module package according to a second preferred embodiment of the present invention.

FIG. 4 to FIG. 7 are schematic views illustrating the manufacturing procedure of the image sensor module package according to the above first preferred embodiment of the present invention.

FIG. 8 is a sectional view illustrating the image sensor module package being bonded to a carrier board according to the above first preferred embodiment of the present invention.

FIG. 9 is a sectional view of an image sensor module package according to a third preferred embodiment of the present invention.

FIG. 10 is a sectional view of an image sensor module package according to a fourth preferred embodiment of the present invention.

FIG. 11 is a sectional view of an image sensor module package according to a fifth preferred embodiment of the present invention.

### DETAILED DESCRIPTION OF THE PREFERRED EMBODIMENT

The following description is disclosed to enable any person skilled in the art to make and use the present invention. Preferable embodiments are provided in the following description only as examples and modifications will be apparent to those skilled in the art. The general principles defined in the following description would be applied to other embodiments, alternatives, modifications, equivalents, and applications without departing from the spirit and scope of the present invention.

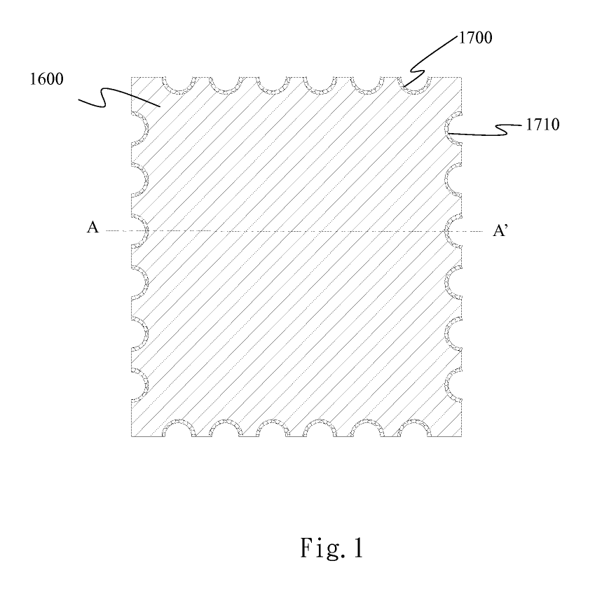

FIG. 1 is a top view of an image sensor module package according to a first preferred embodiment of the present invention. One or more grooves 1700 are provided around an outer circumference of an insulating layer 1600. A metal layer 1710 is provided in each of the grooves 1700 and has a portion protruded from the insulating layer 1600 to perform as an output/input contact.

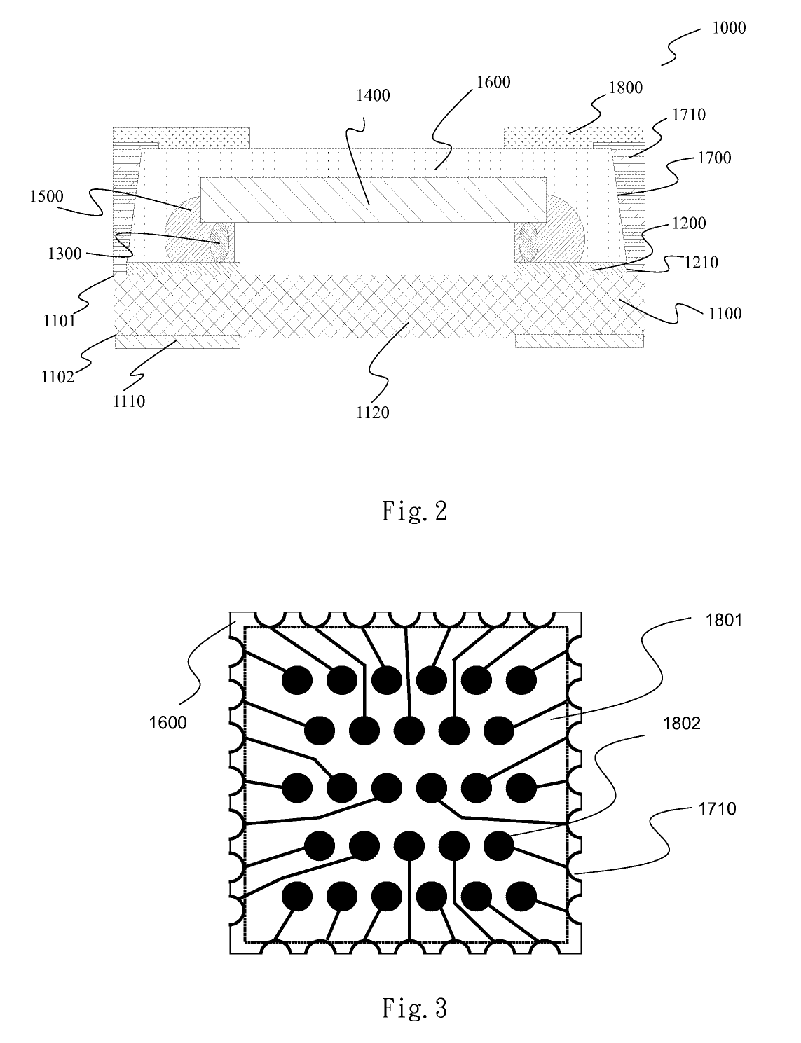

FIG. 2 is a sectional view along line A-A in FIG. 2 illustrating the image sensor module package according to the first preferred embodiment. An image sensor module package 1000 comprises a glass substrate 1100, a circuit layer 1200, a plurality of contacting points 1300, a flip chip 1400, a dam 1500, an insulating layer 1600, at least one groove 1700, and a conducting layer 1800. The conducting layer 18800 is a redistribution layer. The glass substrate 1100 has a first surface 1101, a second surface 1102 and a transparent area 1120. The circuit layer 1200 is patterned on the first surface 1101. The second surface 1102 is coated with an opaque panting to define a position and a shape of the transparent area 1120. The circuit layer 1200, which consists of conducting circuits, is electrically connected to the plurality of contacting points 1300, wherein each of the plurality of contacting points 1300 is a metal bump made of copper. The flip chip 1400, which is a CMOS Image Sensor (CIS), is electrically connected to the plurality of contacting points 1300. The dam 1500, which is made of epoxy resin, is arranged to surround the plurality of contacting points 1300, so as to restrict an overflow of filling material of the insulating layer 1600 since light transmitting through the transparent area 1120 is greatly influenced by the overflow. The flip chip 1400 and the plurality of contact pints 1300 are encased by the insulating layer 1600. Accordingly, the insulating layer 1600 substantially incompletely encases the circuit layer 1200 and exposes at least a contacting surface 1210 of the circuit layer 1200. The insulating layer 1500, which is made of black epoxy-based material, has at least one groove 1700 at a lateral side of said insulating layer thereof, wherein the conducting layer 1800 is provided on a top surface of the insulating layer 1800 which is an output/input contact. Each of the grooves 1700 is provided with a metal layer 1710 having a portion of a thickness of 2 μm which is protruded from the insulating layer 1600. The metal layer 1710, which is made of copper, is connected to the conducting layer 1800 in such a manner that the metal layer 1710 connects the conducting layer 1800 with the contacting surface 1210 of the circuit layer 1200.

Accordingly, the flip chip 1400 of the above first preferred embodiment of the present invention can be replaced with a CMOS image sensor. Each of the plurality of contacting points 1300, which is a metal bump, can be replaced with an Au bump, Sn bump, Cu bump, Ag bump, Ni bump, and Pb-free bump. The dam 1500 is made of epoxy resin. The insulating layer 1600 can be made of organic-based material. The metal layer 1710 can be made of material of Cu, Ag, Au, or any other metal alloy. The portion of the metal layer 1710, which is protruded from the insulating layer 1500, has a thickness larger than 0 μm while not being larger than 10 μm. Therefore, the portion of the metal layer 1710, which can be made of copper, has a relatively small thickness, so that an influence of a thermal stress is prevented. The conducting layer 1800 can be replaced with a redistribution layer 1801.

FIG. 3 is a top view of an image sensor module package according to a second preferred embodiment of the present invention, wherein similar to the image sensor module package of the first preferred embodiment, the conducting layer 1800 is a redistribution layer 1801. According to this preferred embodiment, the redistribution layer 1801 further comprises an output/input contact 1802 to metal wire the circuit to a central area of the insulating layer 1600. And thus the output/input contacts 1802 are not limited to be at positions around the periphery of the insulating layer 1600, so that design of the circuit allows a good flexibility that enables the image sensor module package to be easy to incorporate with other component modules.

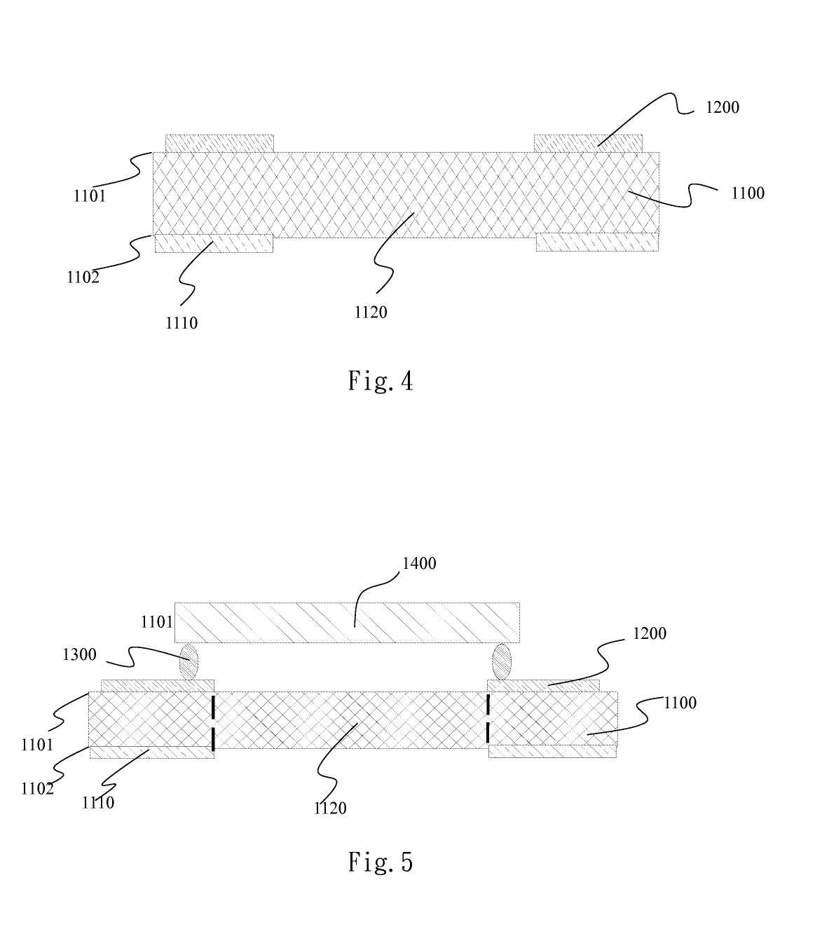

FIG. 4 to FIG. 7 are sectional views illustrating a method of manufacturing the image senor module package of the present invention. Referring to FIG. 4 of the drawing, first of all, a glass substrate 1100 is provided, wherein the glass board 1100 has a first surface 1101, a second surface 1102 and a transparent area 1120, wherein a circuit layer 1200 is patterned on the first surface, an opaque panting 1110 is coated on the second surface 1102 to define a position and a shape of the transparent area 1120, wherein the circuit layer 1200 consists of a plurality of conducting circuits. Referring to FIG. 5 of the drawing, the circuit layer 1200 is connected to at least one contacting point 1300, wherein a flip chip 1400 is connected to the contacting point 1300.

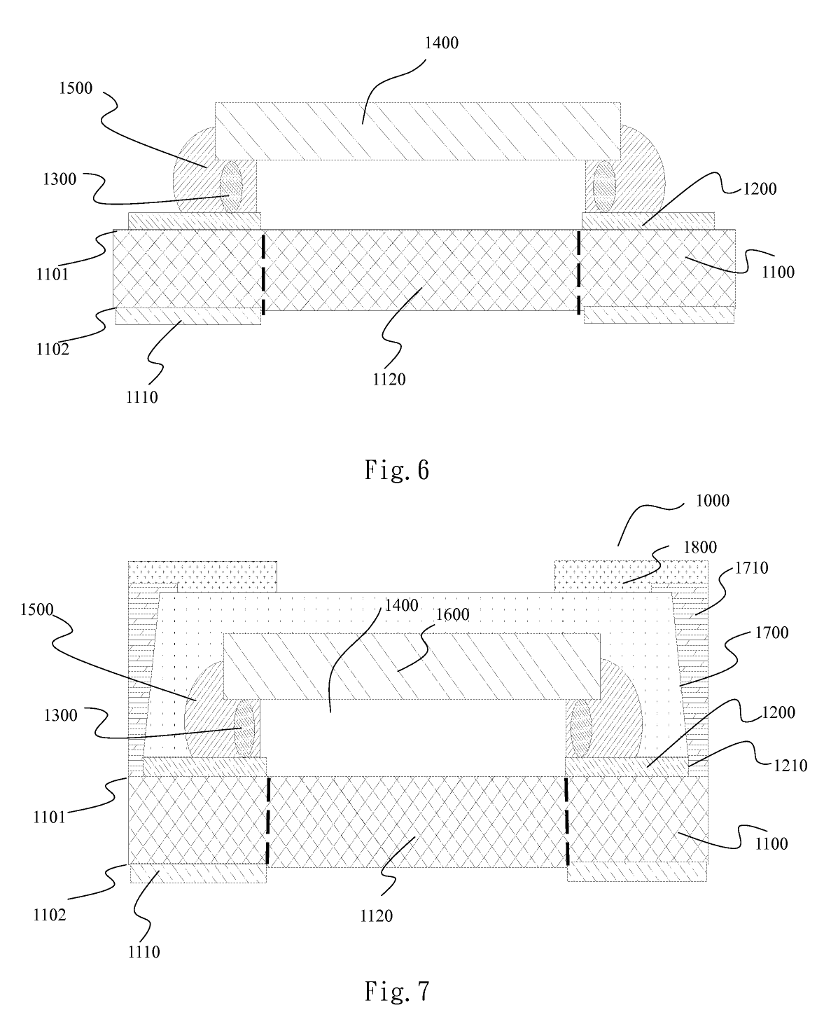

Referring to FIG. 6 of the drawing, a dam 1500 is then provided to surround the contacting point 1300. Referring to FIG. 7 of the drawing, an insulating layer 1600 is formed on the first surface 1101 of the glass substrate 1100, wherein the insulating layer 1600 completely encases the flip chip 1400 and substantially incompletely encases a part of the circuit layer 1200 to expose a contacting surface 1210 of the circuit layer 1200, wherein the insulating layer 1600 is formed by mould filling and a plurality of grooves 1700 is formed at the same time. And then a metal layer 1710 is sputtered in each of the grooves 1700, wherein the metal layer 1710, which is made of copper, has a first end having a thickness of 2 μm protruded from the insulating layer 1600, wherein the first end of the metal layer 1710 is connected to a conducting layer 1800 which is an output/input contact, wherein a second end of the metal layer 1710 is electrically connected to the contacting surface 1210 of the circuit layer 1200.

Accordingly, the conducting layer 1800 can be replaced with a redistribution layer 1801. The plurality of grooves can be formed using molding, etching, mechanical grinding and brushing, laser machining, and the like. The metal layer 1710 can be formed using vapor deposition, sputtering, chemical vapor deposition (CVD), physical vapor deposition (PVD), or electroless plating. The metal layer 1710, which can also be made of Cu, Ag, Au, Ni, or any other metal alloy, has a portion having a thickness larger than 0 μm while not being larger than 10 μm protruded from the insulating layer 1600. Therefore, the portion of the metal layer 1700, which can be made of copper, has a relatively small thickness, so that an influence of a thermal stress is prevented.

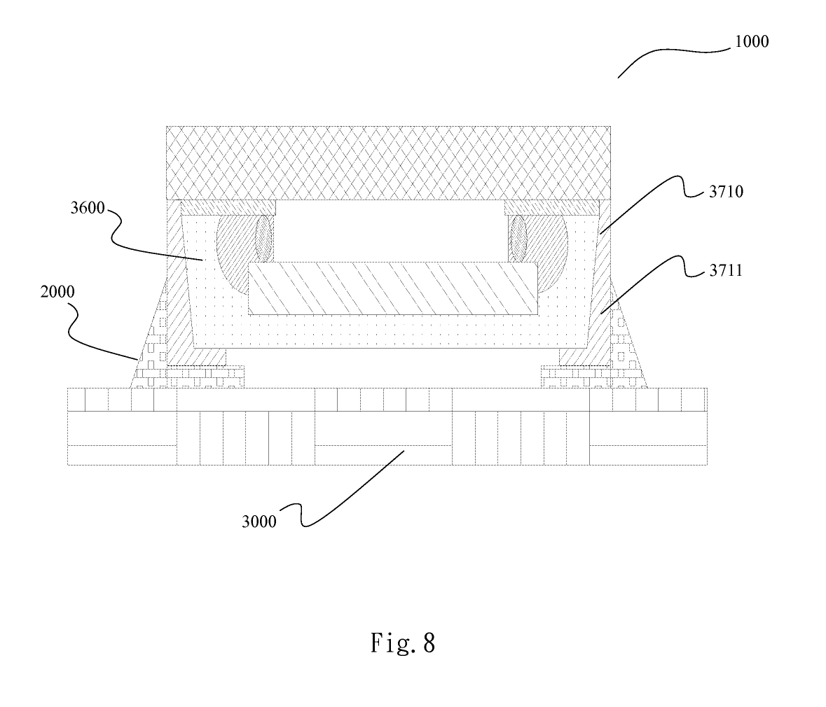

FIG. 8 is a sectional view illustrating the image sensor module package being bonded to a carrier board according to the first preferred embodiment of the present invention. The image sensor module package 1000 is installed to a carrier board 3000, wherein the metal layer 3710 has an open side 3711 exposed from the insulating layer 3600 to provide a relatively large soldering area for connecting with a soldering paste 2000. The soldering paste 2000, which is a Sn paste, connects the image sensor module package 1000 with the carrier board 3000, so that the image sensor module package 1000 is not easy to peel off from the carrier board 3000 which is a circuit board. It is worth to mention that the aforesaid soldering paste can be replaced with a Pb-free paste, while the carried board can be replaced with an IC carrier board.

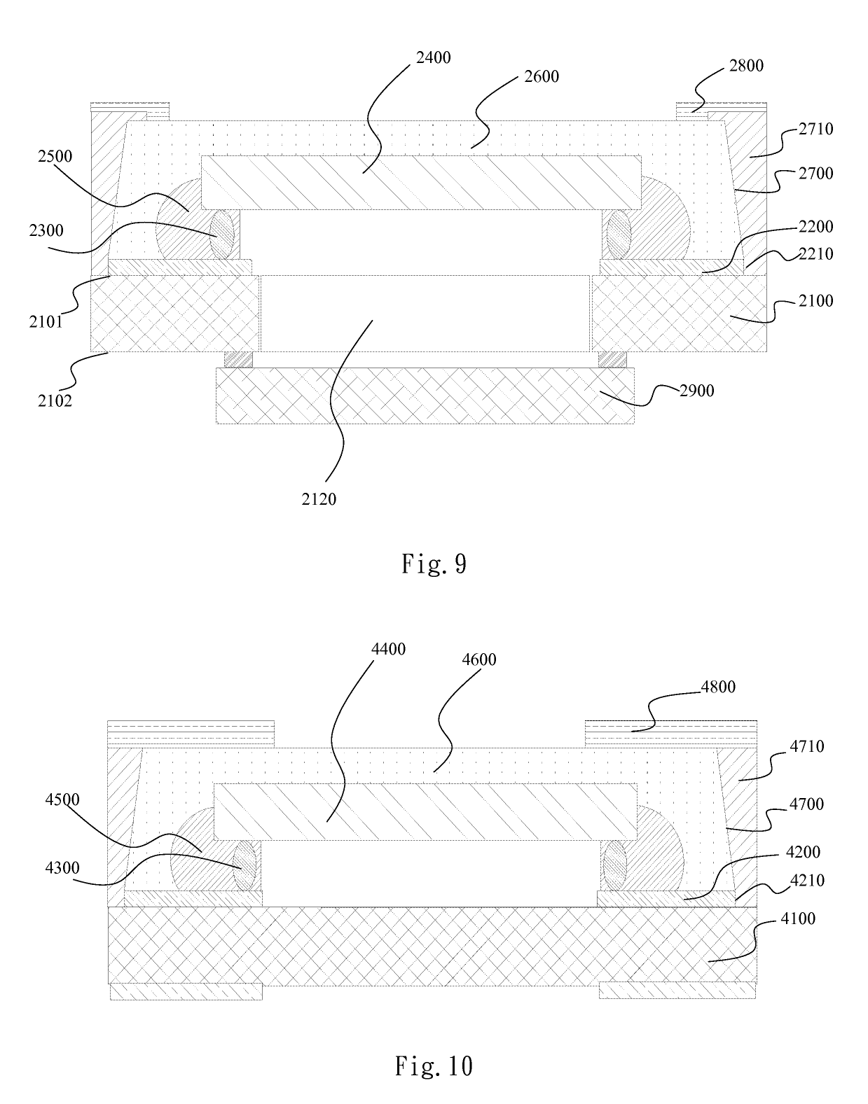

FIG. 9 is a sectional view of an image sensor module package according to a third preferred embodiment of the present invention. The image sensor module package is manufactured by the method illustrated in FIG. 3 to FIG. 6 of the drawings. According to this preferred embodiment, the substrate is a ceramic substreate 2100 having an opening penetrating a first surface 2101 and a second surface 2102, wherein a glass layer 2900 is provided with respect to a position of the opening at the second surface 2102 to form a transparent area 2120 of the ceramic substrate. In addition, the image sensor module package comprises a circuit layer 2200, at least one contacting point 2300, a flip chip 2400, a dam 2500, an insulating layer 2600, at least one groove 2700, a metal layer 2710, and a conducting layer 2800.

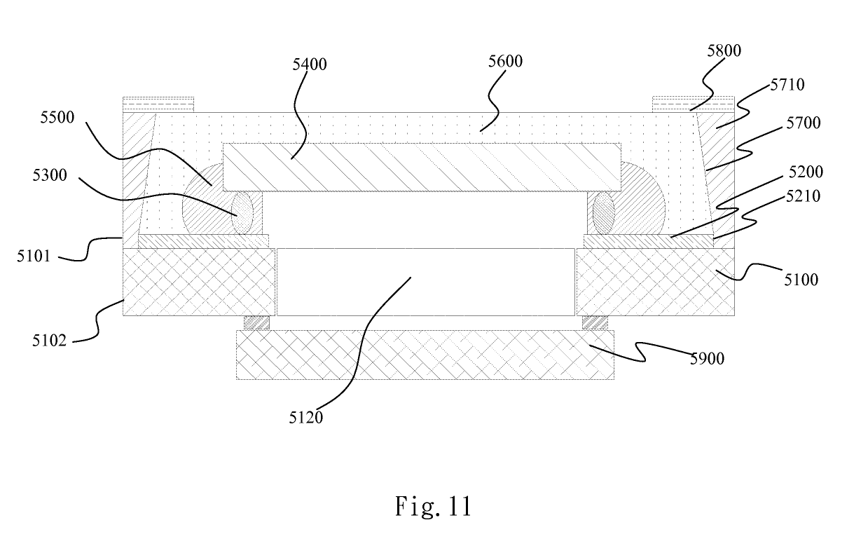

FIG. 10 is a sectional view of an image sensor module package according to a fourth preferred embodiment of the present invention, wherein the image sensor module package has a similar structure with the image sensor module package of the first preferred embodiment illustrated in FIG. 2. According to this preferred embodiment, the substrate is a glass substrate 4100. In addition, the image sensor module package comprises a circuit layer 4200, at least one contacting point 4300, a flip chip 4400, a dam 4500, an insulating layer 4600, at least one groove 4700, and a conducting layer 4800, wherein a metal layer 4710 is provided in each of the grooves 4700. The metal layer 4710, which is made of copper, has a first end which is not protruded from the insulating layer 4600, wherein the firs end is connected to the conducting layer 4800 which is an output/input contact, wherein a second end of the metal layer 4710 is electrically connected to a contacting surface 4210 of the circuit layer 4200.

Accordingly, in this preferred embodiment, the contacting point 4300 is a metal bump which can be replaced with a Au bump, Sn bump, Cu bump, Ag bump, Ni bump, and Pb-free bump. The dam 4500 is made of epoxy resin. The insulating layer 4600 can be made of organic-based material. The metal layer 4710 can be made of material of Cu, Ag, Au, or any other metal alloy. The conducting layer 4800 can be replaced with a redistribution layer. The metal layer 4710 may not have a portion protruded from the insulating layer 4600 so that the drawback caused by the thermal stress is prevented.

FIG. 11 is a sectional view of an image sensor module package according to a fifth preferred embodiment of the present invention. The image sensor module package has a similar structure with the image sensor module package of the above fourth preferred embodiment. According to this preferred embodiment, the base is a ceramic substrate 5100 having an opening penetrating a first surface 5101 and a second surface 5102, wherein a glass layer 5900 is provided with respect to a position of the opening at the second surface 2102 to form a transparent area 5120 of the ceramic substrate. In addition, the image sensor module package comprises a circuit layer 5200, at least one contacting point 5300, a flip chip 5400, a dam 5500, an insulating layer 5600, at least one groove 5700, and a conducting layer 5800, wherein a metal layer 5710 is provided in each of the grooves 5700. The metal layer 5710, which is made of copper, has a first end which is not protruded from the insulating layer 5600, wherein the firs end is connected to the conducting layer 5800 which is an output/input contact, wherein a second end of the metal layer 5710 is electrically connected to a contacting surface 5210 of the circuit layer 5200.

Accordingly, in this preferred embodiment, the contacting point 5300 is a metal bump which can be replaced with a Au bump, Sn bump, Cu bump, Ag bump, Ni bump, and Pb-free bump. The dam 5500 is made of epoxy resin. The insulating layer 5600 can be made of organic-based material. The metal layer 5710 can be made of material of Cu, Ag, Au, or any other metal alloy. The conducting layer 5800 can be replaced with a redistribution layer. The metal layer 5710 may not have a portion protruded from the insulating layer 5600 so that the drawback caused by the thermal stress is prevented.

One skilled in the art will understand that the embodiment of the present invention as shown in the drawings and described above is exemplary only and not intended to be limiting.

It will thus be seen that the objects of the present invention have been fully and effectively accomplished. It embodiments have been shown and described for the purposes of illustrating the functional and structural principles of the present invention and is subject to change without departure from such principles. Therefore, this invention includes all modifications encompassed within the spirit and scope of the following claims.

1. An image sensor module package, comprising:
a substrate having at least a transparent area and defining a first surface and a second surface;
a patterned circuit layer on said first surface of said substrate;
a flip chip connected to said circuit layer;
an insulating layer substantially encasing said flip chip and a part of said circuit layer, wherein said insulating layer has at least a groove provided at a lateral side of said insulating layer thereof, wherein a metal layer is provided in said groove; and
a conducting layer provided on a top surface of said insulating layer, wherein said conducting layer is electrically connected to said circuit layer via said metal layer.

2. The image sensor module package, as recited in claim 1, wherein said substrate is made of glass.

3. The image sensor module package, as recited in claim 1, wherein said substrate, which is made of a material selected from a group consisting of ceramic and organic material, has an opening penetrating said first surface and said second surface, wherein a glass layer is provided with respect to a position of said opening at said second surface to form said transparent area of said substrate.

4. The image sensor module package, as recited in claim 1, wherein said metal layer has an open side exposed from said insulating layer to be connected with a carrier board.

5. The image sensor module package, as recited in claim 1, wherein said conducting layer is a redistribution layer.

6. The image sensor module package, as recited in claim 1, wherein said flip chip further comprises at least one contact point connected to said circuit layer.

7. The image sensor module package, as recited in claim 6, wherein each of said contact points is a metal bump.

8. The image sensor module package, as recited in claim 6, further comprising a dam provided on said circuit layer to prevent said insulating layer from encasing said contact points.

9. A method of packaging an image sensor module, comprising the steps of:
(a) providing a substrate having at least one transparent area;
(b) patterning a circuit layer on said substrate;
(c) bonding a flip chip to said circuit layer;
(d) forming an insulating layer with at least a groove provided at a lateral side of said insulating layer thereof, wherein said insulating layer substantially encases said flip chip and a part of said circuit layer;
(e) providing a metal layer in said groove, and electrically connecting said metal layer to said circuit layer; and
(f) providing a conducting layer on a top surface of said insulating layer, and electrically connecting said conducting layer to said metal layer in said groove.

10. The method, as recited in claim 9, wherein said insulating layer which has at least one said groove is produced by a process selected from the group consisting of molding, etching, mechanical grinding and brushing, and laser machining.

11. The image sensor module package, as recited in claim 2, wherein said flip chip further comprises at least one contact point connected to said circuit layer.

12. The image sensor module package, as recited in claim 3, wherein said flip chip further comprises at least one contact point connected to said circuit layer.

13. The image sensor module package, as recited in claim 4, wherein said flip chip further comprises at least one contact point connected to said circuit layer.

14. The image sensor module package, as recited in claim 5, wherein said flip chip further comprises at least one contact point connected to said circuit layer.

15. The image sensor module package, as recited in claim 11, wherein each of said contact points is a metal bump.

16. The image sensor module package, as recited in claim 12, wherein each of said contact points is a metal bump.

17. The image sensor module package, as recited in claim 13, wherein each of said contact points is a metal bump.

18. The image sensor module package, as recited in claim 14, wherein each of said contact points is a metal bump.

19. The image sensor module package, as recited in claim 11, further comprising a dam provided on said circuit layer to prevent said insulating layer from encasing said contact points.

20. The image sensor module package, as recited in claim 12, further comprising a dam provided on said circuit layer to prevent said insulating layer from encasing said contact points.

21. The image sensor module package, as recited in claim 13, further comprising a dam provided on said circuit layer to prevent said insulating layer from encasing said contact points.

22. The image sensor module package, as recited in claim 14, further comprising a dam provided on said circuit layer to prevent said insulating layer from encasing said contact points.
